(19) United States
(12) Patent Application Publication
(10) Pub. No.: US 2025/0006588 A1
(43) Pub. Date: Jan. 2, 2025

(54) PASSIVE COOLING HEAT SPREADER WITH PHASE CHANGE MATERIAL INFUSED MESH

(71) Applicant: Intel Corporation, Santa Clara, CA (US)

(72) Inventors: Jiun Hann Sir, Gelugor (MY); Poh Boon Khoo, Perai (MY)

(21) Appl. No.: 18/216,830

(22) Filed: Jun. 30, 2023

(51) Int. Cl. H01L 23/427; H01L 21/48; H01L 25/18

(52) U.S. Cl. CPC H01L 23/427; H01L 21/4882; H01L 25/18; H01L 24/16; H01L 2224/16225; H01L 2924/1427

(57) ABSTRACT

A semiconductor assembly may include a package substrate. A semiconductor assembly may include a first semiconductor die on the package substrate. A semiconductor assembly may include a first heat spreader heat spreader is attached to the first semiconductor die opposite the package substrate, the heat spreader comprising a mesh infused with phase change material, wherein the heat spreader is configured to dissipate heat from the first semiconductor die.

### TECHNICAL FIELD

Embodiments described herein generally relate to semiconductor assemblies and thermal regulation methods.

### BACKGROUND

For various semiconductor packages, heat spreaders can be used to help regulate thermal energy therein. It is desired to have heat spreaders and methods that address these concerns, and other technical challenges.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a schematic cross-sectional view of a semiconductor assembly with heat spreaders in an example.

FIG. 2 illustrates an example heat spreader assembly.

FIGS. 3A-3B illustrate an example heat spreader assembly and the heat flow therein.

FIG. 4 illustrates an example heat spreader assembly and the heat flow therein.

FIGS. 5A and 5B illustrate an example process flow of producing a heat spreader assembly.

FIG. 6 illustrates a system level diagram, depicting an example of an electronic device that in an example.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Discussed herein is a heat spreader using a folded metallic mesh. The folded metallic mesh can be soldered to top and bottom surfaces within a semiconductor assembly, and infused with a phase change material (PCM) such as a paraffin based PCM. PCM materials such as parraffin absorb heat energy by changing phase from e.g., a solid phase to a liquid phase. For example, paraffin can remove heat by undergoing a solid state to liquid state phase change. The PCM material that has undergone a solid to liquid phase transition may then transfer that heat by flowing to another, cooler, location and undergoing a liquid to solid phase transition. In accordance with this disclosure a three dimensional (3D) metallic mesh network including a PCM improves heat transfer within the assembly, and specifically allows for improved heat transfer with a PCM matrix. This can help improve paraffin passive cooling thermal responses.

A variety of chips, such as central processing unit (CPU), graphics processing unit (GPU), memory package, and continuous capacitive voltage regulator (C2VR) chips, are increasingly being integrated on single semiconductor packages, such as for mobile devices. For example, some wafer-level packaging uses three dimensional stacking with such chips. As a large number of these “hot” type chips are integrated, such semiconductor packages can get hot enough that conventional heat spreaders may not be sufficient for thermal regulation.

Here, PCM can be used to absorb heat and regulate the temperature of packages that integrate a large number of these types of chips. Use of PCM, for example, in three dimensional stacked packages can keep the package temperature within a normal operating range for a period of time without the need for additional active cooling. PCM itself has a relatively slow thermal response due to low thermal conductivity. For example, paraffin has a 0.2 W/mK thermal conductivity.

Thus, discussed herein is passive cooling technique using a PCM-infused mesh. This combination can enable economic scale usages. Overall, this can allow for more “hot” chips packed into a single package, achieving compact platform system form factors without thermal induced performance constraints. This is a low cost, economic thermal solution. Paraffin PCM specifically can have a variety of different melting temperatures, and thus can be selected to target specific use condition temperature control. For example, paraffin based PCM can have a high heat of fusion, a very low thermal conductivity, and a melt temperature of about −20 to about 100 or more degrees Celsius. Additionally, paraffin PCM has a large latent heat for heat absorption, such as about 200 to 280 KJ/kg. Paraffin PCM can be non-corrosive, with a medium weight, and stable thermal cycling.

In an example, the techniques described herein relate to a semiconductor assembly including: a package substrate; a first semiconductor die on the package substrate; and a first heat spreader heat spreader is attached to the first semiconductor die opposite the package substrate, the heat spreader including a metallic mesh infused with phase change material, wherein the heat spreader is configured to dissipate heat from the first semiconductor die.

In an example, the techniques described herein relate to a semiconductor assembly including: a semiconductor die; and a heat spreader including a metallic mesh infused with phase change material, the heat spreader attached to the semiconductor die and configured to dissipate heat from the semiconductor die.

In an example, the techniques described herein relate to a method of making a heat spreader for a semiconductor assembly including: inserting a metallic mesh inside a heat spreader framework cavity; infusing the metallic mesh with a phase change material; and sealing the heat spreader framework with the phase change material infused metallic mesh therein.

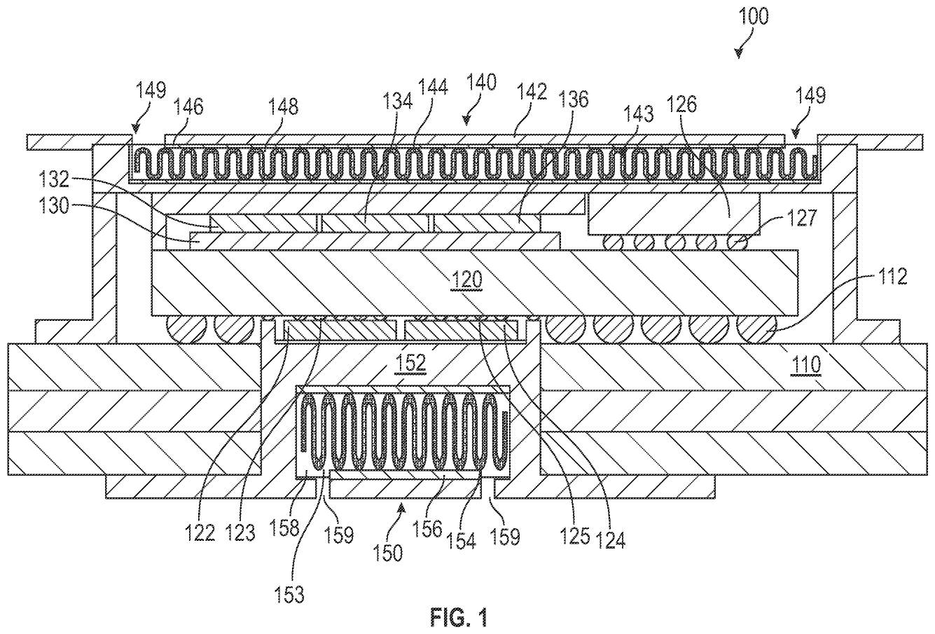

FIG. 1 illustrates a schematic cross-sectional view of a semiconductor assembly 100 with a heat spreaders 140, 150 in an example. The heat spreaders 140, 150 acts as a heat transfer and thermal regulation component.

The semiconductor assembly 100 includes a first heat spreader 140 and a second heat spreader 150. The first heat spreader 140 can include framework 142 with cavity 143, metallic mesh 144, solder 146, and PCM 148, and holes 149. In accordance with this disclosure PCM may comprise a material such as paraffin that is primarily comprised of carbon (C) by weight. The second heat spreader 150 can include framework 152 with cavity 153, metallic mesh 154, solder 156, and

PCM 158, and holes 159. The semiconductor assembly 100 can further include motherboard 110, solder bumps 112, package substrate 120 with first C2VR die 122 and solder bumps 123, second C2VR die 124 and solder bumps 125, memory package 126 with solder bumps 127, base die 130, CPU 132, GPU 134, and SOC die 136.

In the semiconductor assembly 100, the motherboard 110 can host the additional components. The heat spreader 150 can be embedded in the motherboard 110. The first C2VR die 122 and the second C2VR die 124 can be attached to the heat spreader 150 on one side, and, via solder bumps 123 and solder bumps 125, can be attached on an opposing side to the package substrate 120. The package substrate 120 can be attached to the motherboard 110 through the solder bumps 112 on the same side as the first C2VR die 122 and the second C2VR die 124. Opposite the motherboard 110, the package substrate 120 can host the remaining dies. The base die 130 can directly interface with the package substrate 120. The CPU 132, GPU 134, and SOC die 136 can be attached to the base die 130 opposite the package substrate 120. The memory package 126 can be attached to the package substrate 120 through the solder bumps 127. The heat spreader 140 can be attached to the CPU 132, GPU 134, and SOC die 136, in addition to the memory package 126 opposite the package substrate 120.

The motherboard 110 can be, for example, a printed circuit board on which a variety of other components, such as those discussed with reference to semiconductor assembly 100, are attached or mounted. The motherboard 110 can be, for example, made of fiberglass and copper, or other suitable materials. The motherboard 110 can include connections, such as between any of the components including CPU 132 and memory package 126, and the 110//can facilitate communication therebetween.

The package substrate 120 can be, for example, a semiconductor package substrate hosting one or more semiconductor dies such as dies 132, 134, 136, among others. Package substrate 120 can be connected to semiconductor dies 132, 134, 136 through the base die 130. Traces, and other pads or via, can allow for electrical connection through package substrate 120 to other components mounted on a circuit board. In some cases, the package substrate 120 can be mounted on a circuit board, such as the motherboard 110 that mechanically and electrically supports components in the assembly 100, or another type of motherboard.

The central processing unit (CPU) 132, graphics processing unit (GPU) 134, and system on chip (SOC) die 136 can be mounted on the package substrate 120 through the base die 130. In some cases, additional or alternative dies can be used, such as any of a central processing unit (CPU), a platform controller hub/chipset die (PCH), a graphic processing unit (GPU), a memory die, a field programmable gate array (FGPA) or other semiconductor die. In the semiconductor assembly 100 the CPU 132, the GPU 134, and the Die 136 can be electrically coupled to each other through the base die 130.

The base die 130 provide for mechanical stability and robustness of the assembly 100, while allowing electrical connection of the dies 132, 134, 136. In some cases, the base die 130 can include multiple layers, such as carrier layers and/or connection layers, and serve as an interposer. In some cases, the base die 130 can include various layers of dielectric material and/or conductive traces.

The memory package 126 can include one or more memory dies. The memory package 126 can be situated on the package substrate 120. In some cases, the memory package 126 can be physically attached to the package substrate 120, separate from other dies. In some cases, the memory package 126 can be situated near or adjacent the other dies, as desired. The memory package 126 can include sufficient memory as desired. The first C2VR die 122 the second C2VR die 124 can be continuous capacitive voltage regulator dies. Each of the CPU 132, the GPU 134, the die 136, the memory package 126, and C2VR die 122 and the C2VR die 124 can be semiconductor dies that potentially produce heat or hot spots within the semiconductor assembly 100. Each of the CPU 132, the GPU 134, the die 136, the memory package 126, and C2VR die 122 and the C2VR die 124 can be thermally regulated by the heat spreader 140 and/or the heat spreader 150.

The solder bumps 112, 123, 125, and 127 can be used to connect the various dies within the motherboard 110. The solder bumps can be solder balls, such as made of conductive solder in an appropriate pattern to create electrical connections. Such solder balls can be connected to traces in other components made of a conductive material. The solder bumps can be underfilled with an appropriate adhesive, such as, for example, epoxy or other adhesive as known in the art. In some cases, such interconnects can be, for example, solder balls, such as ball grid arrays (BGA) made of conductive solder in an appropriate pattern to create electrical connections. Solder balls can be connected via solder ball pads, made of a conductive and/or metallic material, such as copper.

The heat spreader 140 and the heat spreader 150 can include PCM-infused metallic mesh to help with an even distribution of heat and dispersion of hot spots. For example, in the heat spreaders 140, the framework 142 can be made of an appropriate electrically insulating material, such as a dielectric. The framework 142 can include a cavity 143, such as surrounded by one or more walls. The cavity 143 can be sized and shaped to hold the metallic mesh 144. The framework 142 can have a top and a bottom panel such that the metallic mesh 144 is enclosed within the framework 142. The framework 142 can include one or more holes 149, which can be used during preparation of the heat spreaders 140, and optionally sealed after preparation.

The metallic mesh 144 can be a porous mesh with a large surface area. In an example, the metallic mesh 144 can be a copper mesh. In an example, the metallic mesh 144 can be a sheet with a plurality of regular or irregular pores. In an example, the metallic mesh 144 can have a plurality of holes or slots in a pattern, such as a chevron pattern. The metallic mesh 144 can be folded within the framework 142. The metallic mesh 144 can be folded repeatedly to create additional surface area thereon. In other examples, the metallic mesh 144 can be a solid sheet with no holes that is folded, or can be a solid block that has a grid pattern cut into it.

The folded metallic mesh 144 can be attached within the cavity 143 of the framework 142 through the solder 146. Once the metallic mesh 144 is situated within the cavity 143, the PCM 148 can be injected therein. The PCM 148 can be injected through the holes 149. The PCM 148 can be infused throughout and around the metallic mesh 144.

The heat spreaders 140 and 150 can allow for dissipation and spreading of thermal energy within the semiconductor assembly 100. The combination of the high surface area metallic mesh with the PCM can help move such heat throughout the semiconductor assembly 100 and dissipate heat spots. In the example semiconductor assembly 100, the heat spreader 140 can be on the top of the semiconductor assembly 100, while heat spreader 150 can be on the bottom of the semiconductor assembly 100. In some examples, the heat spreader can be on the top or the bottom of the assembly, or both, depending in desired thermal regulation.

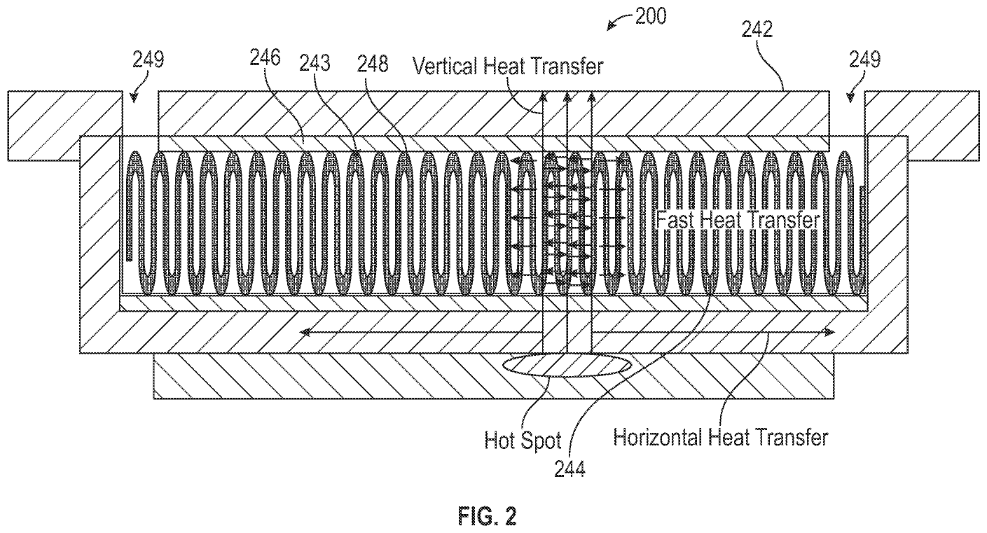

FIG. 2 illustrates an example heat spreader assembly 200. Here, the assembly 200 can include framework 242 with cavity 243, metallic mesh 244, solder 246, and PCM 248, and holes 249, similar to those components discussed above with reference to FIG. 1. The paraffin of the PCM 248 can have a low thermal conductivity, such as about 0.2 W·mK. This can allow for relatively slow heat transfer inside the PCM 248. Such a slow thermal response can cause delayed passive cooling effects, which can be beneficial in the assembly 200. The folded copper mesh 248, embedded with paraffin, can improve heat transfer.

The folded copper mesh 244 is internal in the heat spreader assembly 200, infused with the PCM 248, and the assembly is soldered on top and bottom surfaces. For this reason, the structure of the assembly 200 is not outwardly detectable, but could be seen through cross-section or imaging.

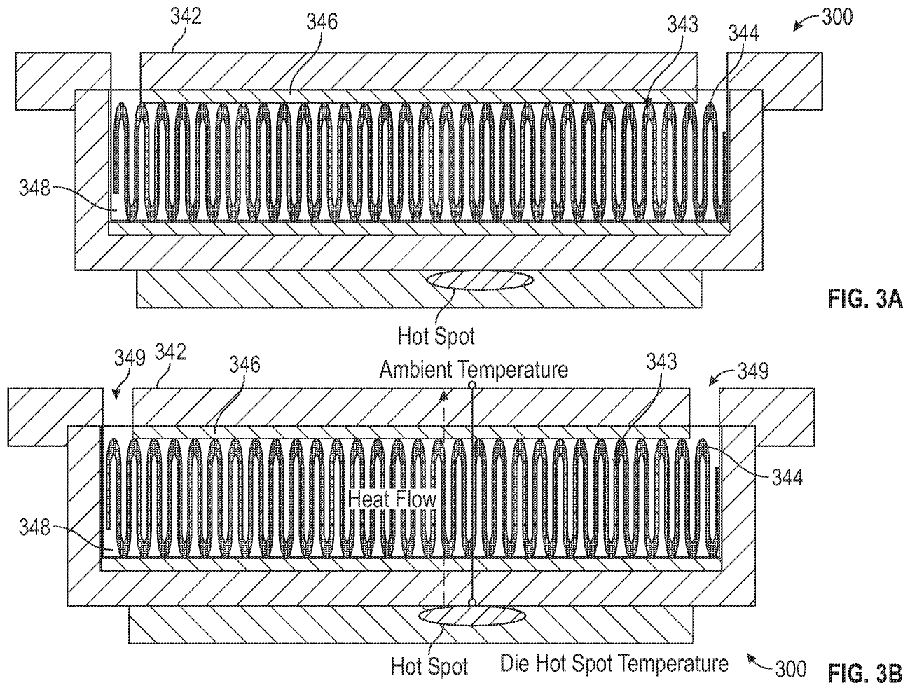

FIGS. 3A-3B illustrate an example heat spreader assembly 300 and the heat flow therein. Here, the assembly 300 can include framework 342 with cavity 343, metallic mesh 344, solder 346, and PCM 348, and holes 349, similar to those components discussed above with reference to FIG. 1.

The heat spreader assembly 300 has a cavity 343 that is filled with the folded metallic mesh 344. The folded copper metallic mesh 344 can be soldered with solder 346 to the heat spreader framework 342 on both the top and bottom. The solder can allow for undisturbed thermal conductivity between the heat spreader and the mesh 344. With the large gradient temperature between ambient temperature on the framework 342 and hot sports on the die surface, this can promote vertical heat transfer through the folded copper mesh 344. The folded mesh 344 can have good thermal conductivity and increased surface contact area between the PCM 348. This can allow faster heat transfer onto the paraffin PCM 348 and improve the paraffin passive cooling thermal response. This can be used as a top and/or bottom thermal solution for a semiconductor die package.

In FIG. 3A, the PCM 348 can be a different variant of paraffin PCM, such as a variation of paraffin with a different melting temperature and high latent heat properties. Here, solder in the assembly 300 can help ensure undisturbed thermal conductivity between the outer surfaces of the heat spreader assembly 300 and the copper mesh 344.

In FIG. 3B, a different type of mesh 344 can be used, such as with a different pore size. In some cases, mesh 344 with different cross sectional shaped pores can be used. In FIG. 3B, there can be a large gradient temperature between ambient temperature on the heat spreader surface and hot spot temperature on the die surface. This can promote vertical heat transfer through the folded mesh 344 metal network.

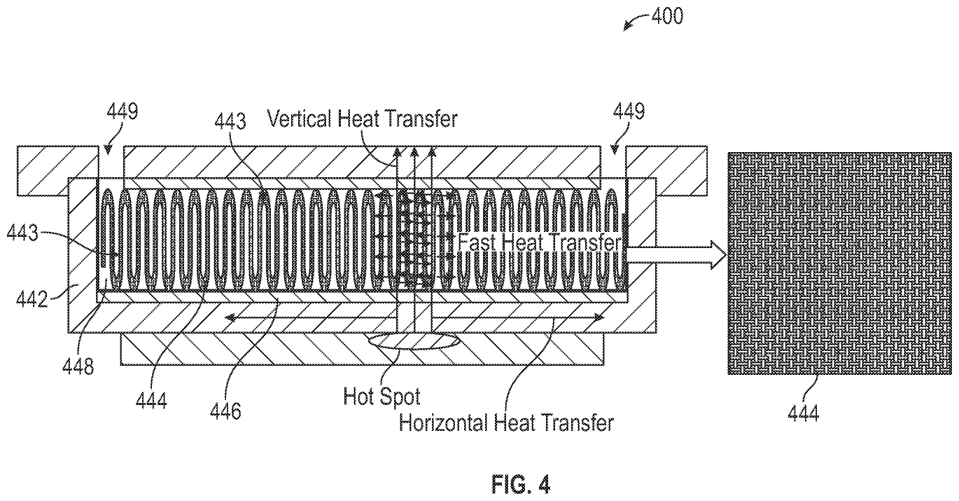

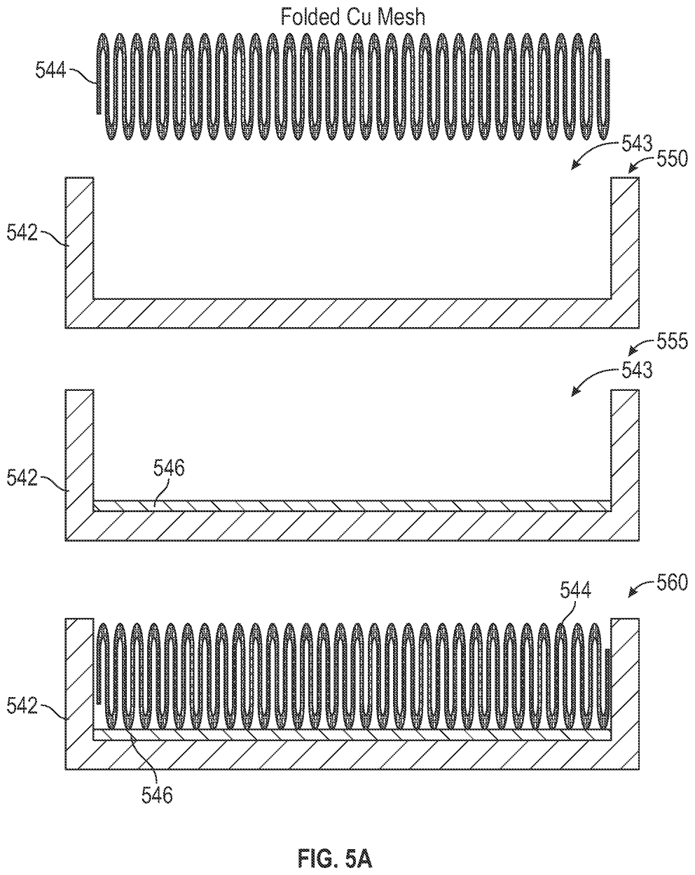

FIG. 4 illustrates an example heat spreader assembly 400 and the heat flow therein. Here, the assembly 400 can include framework 442 with cavity 443, metallic mesh 444, solder 446, and PCM 448, and holes 449, similar to those components discussed above with reference to FIG. 1. The metallic mesh 444 thermal conductivity and the large surface contact area between the metallic mesh 444 and the paraffin PCM 448 can allow for good heat transfer and improve passive cooling thermal response.

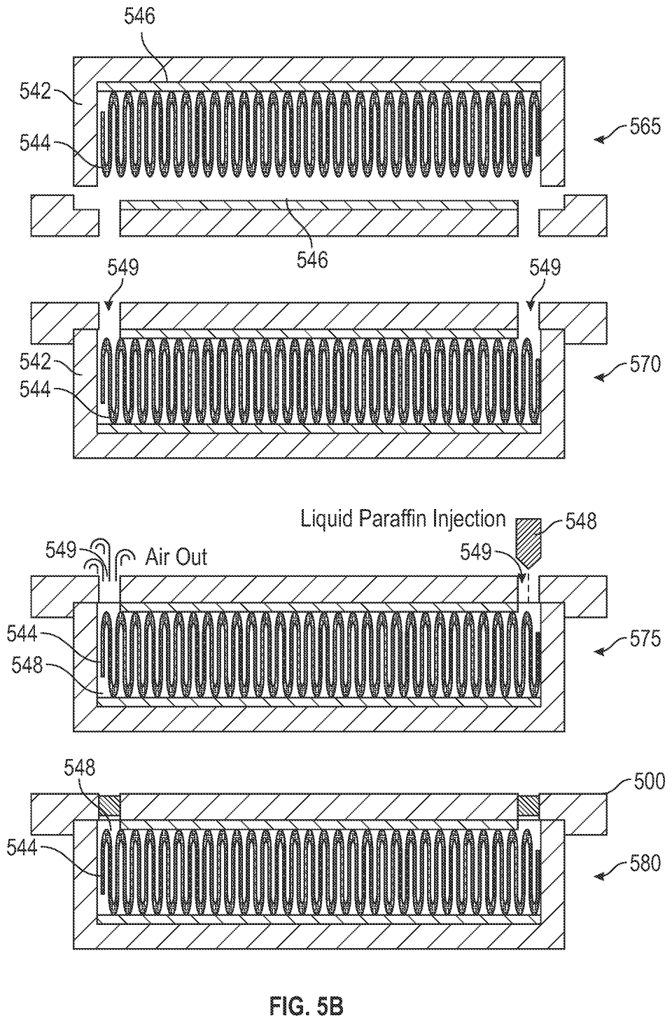

FIG. 5 illustrates an example process flow of producing heat spreader assembly 500. Here, the assembly 500 can include framework 542 with cavity 543, metallic mesh 544, solder 546, and PCM 548, and holes 549, similar to those components discussed above with reference to FIG. 1.

First, at step 550, the heat spreader framework 542 can be prepared, and the metallic mesh 544 can be folded. At step 555, solder 546 paste can be applied to the cavity 543 can be applied. At step 560, the metallic mesh 544 can be inserted into the cavity 543, and the folded metallic mesh 544 can be inter-connected to the solder 546.

At step 565, solder 546 can be applied to the framework on the opposing side and can be inter-connected, such as ply reflow. At step 570, the metallic mesh 544 can be bonded to the framework 542 to ensure thermal conductivity between the mesh 544 and the framework 542 for vertical heat flow.

At step 575, the heat spreader framework 542 cavity 543 can be filled with paraffin PCM 548 using an injection method. At step 580, the holes can be sealed to prevent paraffin leaking during a melting phase. The holes 549 can be sealed with solder or thermal sealant materials.

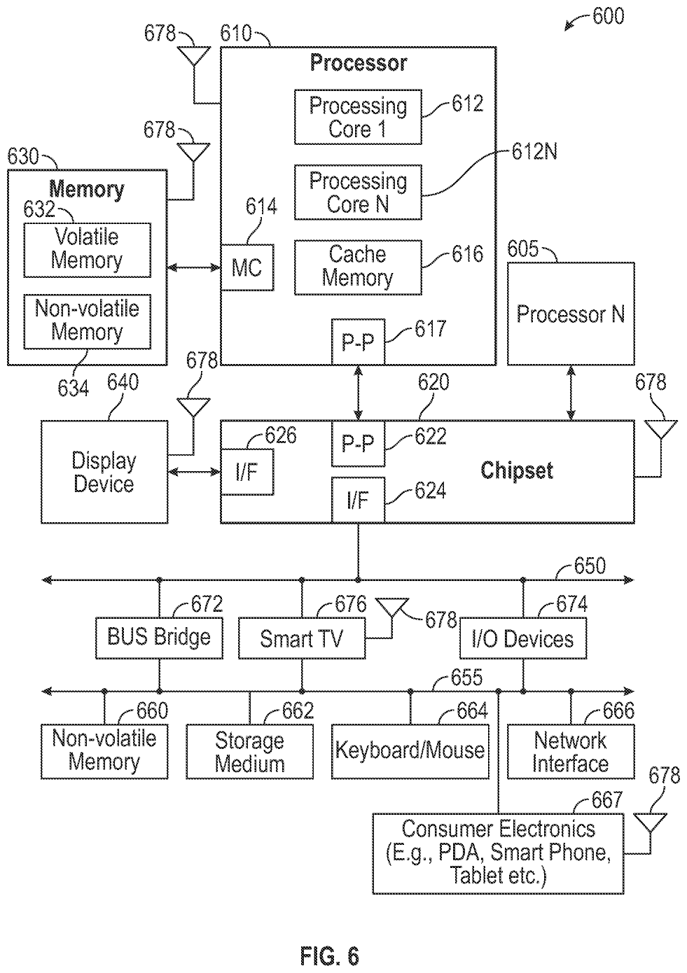

FIG. 6 illustrates a system level diagram, depicting an example of an electronic device (e.g., system) that may include a heat spreader assembly and/or methods described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 includes a system on a chip (SOC) system.

In one embodiment, processor 610 has one or more processor cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices, including a bus bridge 672, a smart TV 676, I/O devices 674, nonvolatile memory 660, a storage medium (such as one or more mass storage devices) 662, a keyboard/mouse 664, a network interface 666, and various forms of consumer electronics 677 (such as a PDA, smart phone, tablet etc.), etc. In one embodiment, chipset 620 couples with these devices through an interface 624. Chipset 620 may also be coupled to a wireless antenna 678 to communicate with any device configured to transmit and/or receive wireless signals. In one example, any combination of components in a chipset may be separated by a continuous flexible shield as described in the present disclosure.

Chipset 620 connects to display device 640 via interface 626. Display 640 may be, for example, a liquid crystal display (LCD), a light emitting diode (LED) array, an organic light emitting diode (OLED) array, or any other form of visual display device. In some embodiments of the example system, processor 610 and chipset 620 are merged into a single SOC. In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

### VARIOUS NOTES & EXAMPLES

To better illustrate the method and apparatuses disclosed herein, a non-limiting list of embodiments is provided here:

Example 1 is a semiconductor assembly comprising: a package substrate; a first semiconductor die on the package substrate; and a first heat spreader heat spreader is attached to the first semiconductor die opposite the package substrate, the heat spreader comprising a metallic mesh infused with phase change material, wherein the heat spreader is configured to dissipate heat from the first semiconductor die.

In Example 2, the subject matter of Example 1 optionally includes wherein the metallic mesh comprises a folded copper mesh.

In Example 3, the subject matter of any one or more of Examples 1-2 optionally include wherein the phase change material comprises paraffin.

In Example 4, the subject matter of any one or more of Examples 1-3 optionally include wherein the heat spreader further comprises a framework attached to the metallic mesh.

In Example 5, the subject matter of Example 4 optionally includes wherein the heat spreader further comprises solder attaching the framework to the metallic mesh.

In Example 6, the subject matter of any one or more of Examples 1-5 optionally include wherein the first semiconductor die comprises a computer processing unit or a graphics processing unit.

In Example 7, the subject matter of any one or more of Examples 1-6 optionally include a second semiconductor die attached to the package substrate opposite the first semiconductor die.

In Example 8, the subject matter of Example 7 optionally includes a second heat spreader attached to the second semiconductor die opposite the package substrate, wherein the heat spreader comprises a metallic mesh infused with phase change material.

In Example 9, the subject matter of any one or more of Examples 7-8 optionally include wherein the second semiconductor die comprises a continuous capacitive voltage regulator chip.

In Example 10, the subject matter of any one or more of Examples 1-9 optionally include a memory package attached between the substrate package and the first heat spreader.

In Example 11, the subject matter of any one or more of Examples 1-10 optionally include a motherboard attached to the package substrate.

Example 12 is a semiconductor assembly comprising: a semiconductor die; and a heat spreader comprising a metallic mesh infused with phase change material, the heat spreader attached to the semiconductor die and configured to dissipate heat from the semiconductor die.

In Example 13, the subject matter of Example 12 optionally includes wherein the metallic mesh comprises copper mesh.

In Example 14, the subject matter of any one or more of Examples 12-13 optionally include wherein the metallic mesh has a thermal conductivity of about 390 to about 410 W/mK.

In Example 15, the subject matter of any one or more of Examples 12-14 optionally include wherein the metallic mesh is folded within the heat spreader.

In Example 16, the subject matter of any one or more of Examples

12-15 optionally include wherein the metallic mesh comprises a porous sheet of metallic material.

In Example 17, the subject matter of any one or more of Examples 12-16 optionally include wherein the phase change material comprises paraffin. In Example 18, the subject matter of any one or more of Examples

12-17 optionally include wherein the phase change material has a thermal conductivity of 0.5 W/mK or less.

Example 19 is a method of making a heat spreader for a semiconductor assembly comprising: inserting a metallic mesh inside a heat spreader framework cavity; infusing the metallic mesh with a phase change material; and sealing the heat spreader framework with the phase change material infused metallic mesh therein.

In Example 20, the subject matter of Example 19 optionally includes folding the metallic mesh prior to inserting the metallic mesh into the heat spreader framework.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

What is claimed is:

1. A semiconductor assembly comprising:
a package substrate;
a first semiconductor die on the package substrate; and
a first heat spreader attached to the first semiconductor die opposite the package substrate, the heat spreader comprising a metal mesh infused with a material primarily comprising carbon by weight.

2. The assembly of claim 1, wherein the metal mesh comprises copper.

3. The assembly of claim 1, wherein the material comprises paraffin.

4. The assembly of claim 1, wherein the heat spreader further comprises a framework attached to the metal mesh.

5. The assembly of claim 4, wherein the heat spreader further comprises solder attaching the framework to the metal mesh.

6. The assembly of claim 1, wherein the first semiconductor die comprises a computer processing unit or a graphics processing unit.

7. The assembly of claim 1, further comprising a second semiconductor die attached to the package substrate opposite the first semiconductor die.

8. The assembly of claim 7, further comprising a second heat spreader attached to the second semiconductor die opposite the package substrate, wherein the heat spreader comprises a metal mesh infused with the material.

9. The assembly of claim 7, wherein the second semiconductor die comprises a continuous capacitive voltage regulator chip.

10. The assembly of claim 1, further comprising a memory package attached between the substrate package and the first heat spreader.

11. The assembly of claim 1, further comprising a motherboard attached to the package substrate.

12. A semiconductor assembly comprising:
a semiconductor die; and
a heat spreader comprising a mesh infused with phase change material, the heat spreader attached to the semiconductor die and configured to dissipate heat from the semiconductor die.

13. The assembly of claim 12, wherein the mesh comprises copper mesh.

14. The assembly of claim 12, wherein the mesh has a thermal conductivity of about 390 to about 410 W/mK.

15. The assembly of claim 12, wherein the mesh is folded within the heat spreader.

16. The assembly of claim 12, wherein the mesh comprises a porous sheet of metallic material.

17. The assembly of claim 12, wherein the phase change material comprises paraffin.

18. The assembly of claim 12, wherein the phase change material has a thermal conductivity of 0.5 W/mK or less.

19. A method of making a heat spreader for a semiconductor assembly comprising:
inserting a mesh inside a heat spreader framework cavity;
infusing the mesh with a phase change material; and
sealing the heat spreader framework with the phase change material infused mesh therein.

20. The method of claim 19, further comprising folding the mesh prior to inserting the mesh into the heat spreader framework.
